(19) United States
(12) Patent Application Publication
(10) Pub. No.: US 2023/0238067 A1
(43) Pub. Date: Jul. 27, 2023

(54) METHOD OF PROGRAMMING AND VERIFYING MEMORY DEVICE AND RELATED MEMORY DEVICE

(71) Applicant: YANGTZE MEMORY TECHNOLOGIES CO., LTD., Wuhan (CN)

(72) Inventors: XiangNan Zhao, Wuhan (CN); Yali Song, Wuhan (CN); An Zhang, Wuhan (CN); Hongtao Liu, Wuhan (CN); Lei Jin, Wuhan (CN)

(21) Appl. No.: 18/125,714

(22) Filed: Mar. 23, 2023

Related U.S. Application Data
(63) Continuation-in-part of application No. 17/164,795, filed on Feb. 1, 2021.
Application No. 17/164,795 is a continuation of application No. 16/699,743, filed on Dec. 2, 2019, now Pat. No. 10,943,665.
Application No. 16/699,743 is a continuation of application No. PCT/CN2019/111830, filed on Oct. 18, 2019.

(51) Int. Cl. G11C 16/34; G11C 11/56; G11C 16/08; G11C 16/12

(52) U.S. Cl. CPC G11C 16/3481; G11C 11/5628; G11C 16/08; G11C 16/12; G11C 16/3459; G11C 2211/5621

(57) ABSTRACT

When programming and verifying a memory device which includes a plurality of memory cells and a plurality of word lines, a first coarse programming is first performed on a first memory cell among the plurality of memory cells which is controlled by a first word line among the plurality of word lines, and then a second coarse programming is performed on a second memory cell among the plurality of memory cells which is controlled by a second word line among the plurality of word lines. Next, a first coarse verify current is used for determining whether the first memory cell passes a coarse verification and a second coarse verify current is used for determining whether the second memory cell passes a second coarse verification, wherein the second coarse verify current is smaller than the first coarse verify current.

### CROSS REFERENCE TO RELATED APPLICATIONS

This application is a continuation-in-part of U.S. application Ser. No. 17/164,795, filed on Feb. 1, 2021, which is a continuation of U.S. application Ser. No. 16/699,743, filed on Dec. 2, 2019, issued as U.S. Pat. No. 10,943,665, which is a continuation of International Application No. PCT/CN2019/111830, filed on Oct. 18, 2019, all of which are incorporated herein by reference in their entireties.

### BACKGROUND

The present disclosure is related to a method of programming and verifying a memory device and related memory device, and more particularly, to a method of programming and verifying a memory device with 3D QLC structure and a related memory device.

Semiconductor memory has become more popular for use in various electronic devices. For example, non-volatile semiconductor memory is applied in cellular telephones, digital cameras, personal digital assistants, mobile computing devices, non-mobile computing devices and other devices. Recently, ultra high density storage devices have been proposed using a three-dimensional (3D) stacked memory structure sometimes referred to as a Bit Cost Scalable (BiCS) architecture. For example, a 3D NAND stacked flash memory device can be formed from an array of alternating conductive and dielectric layers. A memory hole is drilled in the layers to define many memory layers simultaneously. A NAND string is then formed by filling the memory hole with appropriate materials. Control gates of the memory cells are provided by the conductive layers.

Each planar NAND memory consists of an array of memory cells connected by multiple word lines and bit lines. In order to mitigate the effect of floating gate-to-floating gate coupling, a 3D QLC NAND memory may be programmed through coarse and fine programming to improve overall programming speed. Also, a coarse/fine verify is performed according to a constant coarse/fine verify current after each step of coarse/fine programming to determine whether the selected memory cell has reached a desired value.

In a prior art coarse/fine programming method, the difference between the coarse verify current and the fine verify current is set in a way to result in a constant voltage difference on the current-voltage curve of a 3D QLC NAND memory device. As the 3D QLC NAND memory device adopts more layers, the difference between the best-of-current (BOC) case current-voltage curve and the worse-of-current (WOC) case current-voltage curve also increases, resulting in larger gain variations among different memory cells. Therefore, the prior art coarse/fine programming method has a small margin on the threshold voltages of the memory cells.

### SUMMARY

The present disclosure provides a method of programming and verifying a memory device which includes a plurality of memory cells and a plurality of word lines. The method includes performing a first coarse programming on a first memory cell among the plurality of memory cells which is controlled by a first word line among the plurality of word lines, performing a second coarse programming on a second memory cell among the plurality of memory cells which is controlled by a second word line among the plurality of word lines after performing the first coarse programming on the first memory cell, determining whether the first memory cell passes a coarse verification according to a first coarse verify current, and determining whether the second memory cell passes a second coarse verification according to a second coarse verify current smaller than the first coarse verify current.

The present disclosure also provides a memory device which includes a memory cell array having a plurality of memory cells, a plurality of word lines, a word line driver and a controller. The controller is configured to perform a first coarse programming on a first memory cell controlled by a first word line among the plurality of word lines, perform a second coarse programming on a second memory cell controlled by a second word line among the plurality of word lines after performing the first coarse programming on the first memory cell, determine whether the first memory cell passes a coarse verification according to a first coarse verify current; and determine whether the second memory cell passes a second coarse verification according to a second coarse verify current smaller than the first coarse verify current.

### BRIEF DESCRIPTION OF THE DRAWINGS

FIG. 1A is an Id-Vg curve illustrating the characteristic of best of current (BOC) scenario and worst of current (WOC) scenario under coarse verify operation and fine verify operation.

FIG. 1B is a chart illustrating a threshold voltage distribution of a memory cell under a 3 bit line (3BL) programming scheme according to an implementation of the present disclosure.

FIG. 2A is a top-view diagram illustrating one NAND string according to an implementation of the present disclosure.

FIG. 2B is a diagram illustrating an equivalent circuit of one NAND string according to an implementation of the present disclosure.

FIG. 2C is a side view of a cross-section of an exemplary memory device according to an implementation of the present disclosure.

FIG. 2D is a plan view of an exemplary memory device according to an implementation of the present disclosure.

FIG. 3A is a diagram illustrating an exemplary structure of a memory cell array according to an implementation of the present disclosure.

FIG. 3B is a diagram illustrating another exemplary structure of a memory cell array according to an implementation of the present disclosure.

FIG. 4A is a block diagram of a memory device according to an implementation of the present disclosure.

FIG. 4B is a block diagram of a memory device according to an implementation of the present disclosure.

FIG. 4C is a block diagram of a memory system including a memory controller according to an implementation of the present disclosure.

FIG. 5 is a flowchart illustrating a method of programming a memory cell array in a memory device according to an implementation of the present disclosure.

FIGS. 6A and 6B are diagrams illustrating the waveform of the programming voltage when programming a memory cell array in a memory device according to an implementation of the present disclosure.

FIG. 6C is a diagram illustrating the value of the coarse verify current associated with each word line subset according to an implementation of the present disclosure.

FIGS. 6D and 6E are diagrams illustrating the waveform of the verify voltages when programming a memory cell array in a memory device according to an implementation of the present disclosure.

FIG. 6F is a diagram illustrating a sequence of program operations and verify operations in a 3BL program scheme according to an implementation of the present disclosure.

FIG. 7 is a voltage-time (V-t) chart illustrating the voltage at a sense-out (SO) node and during an SO development phase.

FIG. 8A a flowchart illustrating a method of programming a memory cell array in a memory device using a 3 bit line (3BL) program method according to an implementation of the present disclosure.

FIG. 8B is a block diagram of word line subsets according to an implementation of the present disclosure.

FIG. 8C is a block diagram of word line subsets according to an implementation of the present disclosure.

FIG. 9 illustrates a block diagram of an exemplary system having a memory device, according to some implementations of the present disclosure.

FIG. 10A illustrates a diagram of an exemplary memory card having a memory device, according to some implementations of the present disclosure.

FIG. 10B illustrates a diagram of an exemplary solid-state drive (SSD) having a memory device, according to some implementations of the present disclosure.

### DETAILED DESCRIPTION

In the following detailed description, reference is made to the accompanying drawing that show, by way of illustration, specific implementations in which the disclosure may be practiced. These implementations are described in sufficient detail to enable those skilled in the art to practice the disclosure. It is to be understood that the various implementations of the disclosure, although different, are not necessarily mutually exclusive. For example, a particular feature, structure, or characteristic described herein in connection with one implementation may be implemented within other implementations without departing from the spirit and scope of the disclosure. In addition, it is to be understood that the location or arrangement of individual elements within each disclosed implementation may be modified without departing from the spirit and scope of the disclosure. The following detailed description is, therefore, not to be taken in a limiting sense, and the scope of the present disclosure is defined only by the appended claims, appropriately interpreted, along with the full range of equivalents to which the claims are entitled. In the drawings, like numerals refer to the same or similar functionality throughout the several views.

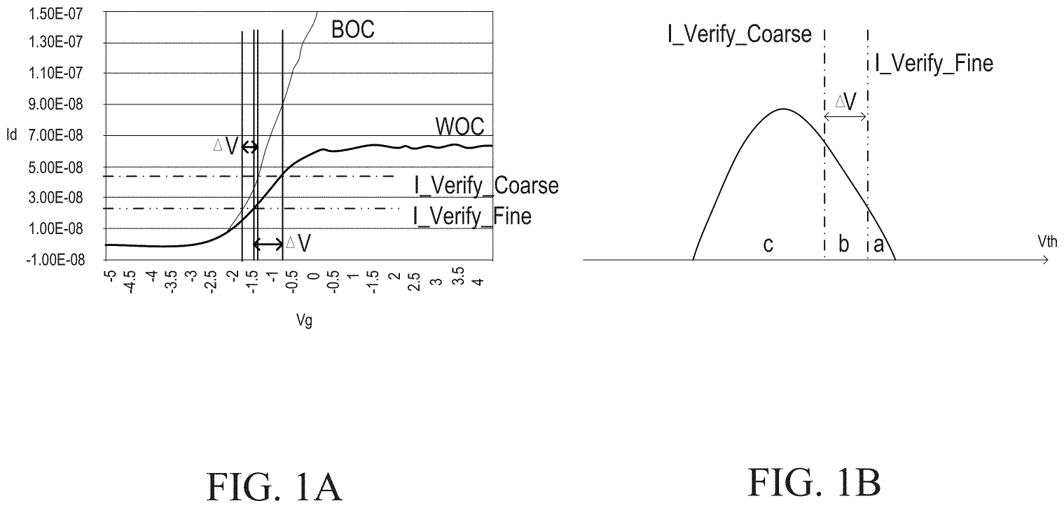

FIG. 1A is an Id-Vg curve illustrating the characteristic of best of current (BOC) scenario and worst of current (WOC) scenario under coarse verify operation and fine verify operation. When stacks of 3D NAND memory device increase, as shown in FIG. 1A, the channel current decreases, and the difference between the characteristic of corresponding BOC and WOC becomes significant. The variation between the transconductance (gm) of BOC and WOC also becomes larger. A 3BL program scheme may improve the distribution of threshold voltage at each program state. That is, it may approximately reduce the width of the threshold voltage distribution of memory cells by half thereby improving the reliability of the memory device. However, when the variation between the transconductance (gin) of BOC and WOC becomes larger, the 3BL program scheme may not have such a great effect. FIG. 1B is a chart illustrating a threshold voltage distribution of a memory cell under a 3 bit line (3BL) programming scheme according to an implementation of the present disclosure. As shown in FIG. 1B, it is required that, during the fine verify operation and coarse verify operation, the ΔV—a verify voltage difference between fine verify operation and coarse verify operation, should be retained as constant (e.g., approximately a half of the step of an incremental-step-pulse programming (ISPP)). However, due to the variation of transconductance (gm), the ΔV of corresponding BOC and WOC are different and cannot be kept as constant. Specifically, after memory cells are programmed in a first loop of a program verify operation, a coarse verify signal (e.g., a coarse verify voltage or current) is applied to a word line corresponding to the memory cells to determine whether threshold voltages of each memory cells are within a region c, or within a region a+ a region b, during a first verify phase. Next, a fine verify signal (e.g., a fine verify voltage or current) is applied to a word line corresponding to the memory cells to determine whether threshold voltages of each memory cells are within the region b, or within the region a, during a second verify phase. As such, in a next loop of the program verify operation, a high voltage (e.g., a system voltage Vdd) will be applied to bit lines corresponding to the memory cells with threshold voltages in region a to inhibit the memory cells from further programmed. Meanwhile, in the next loop of the program verify operation, a low voltage (e.g., a zero or ground voltage) will be applied to bit lines corresponding to the memory cells with threshold voltages in region c to program the memory cells to the target program state in a normal speed. Also, in the next loop of the program verify operation, an intermediate voltage (e.g., a Vb) will be applied to bit lines corresponding to the memory cells with threshold voltages in region b to program the memory cells to the target program state in a slower speed than the normal speed. By doing so, it may reduce the time programming all or almost all the memory cells to the target program state.

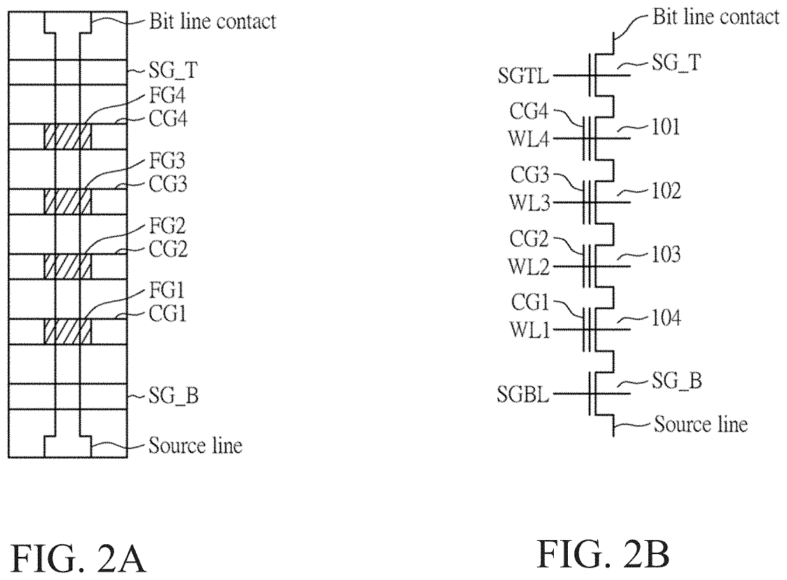

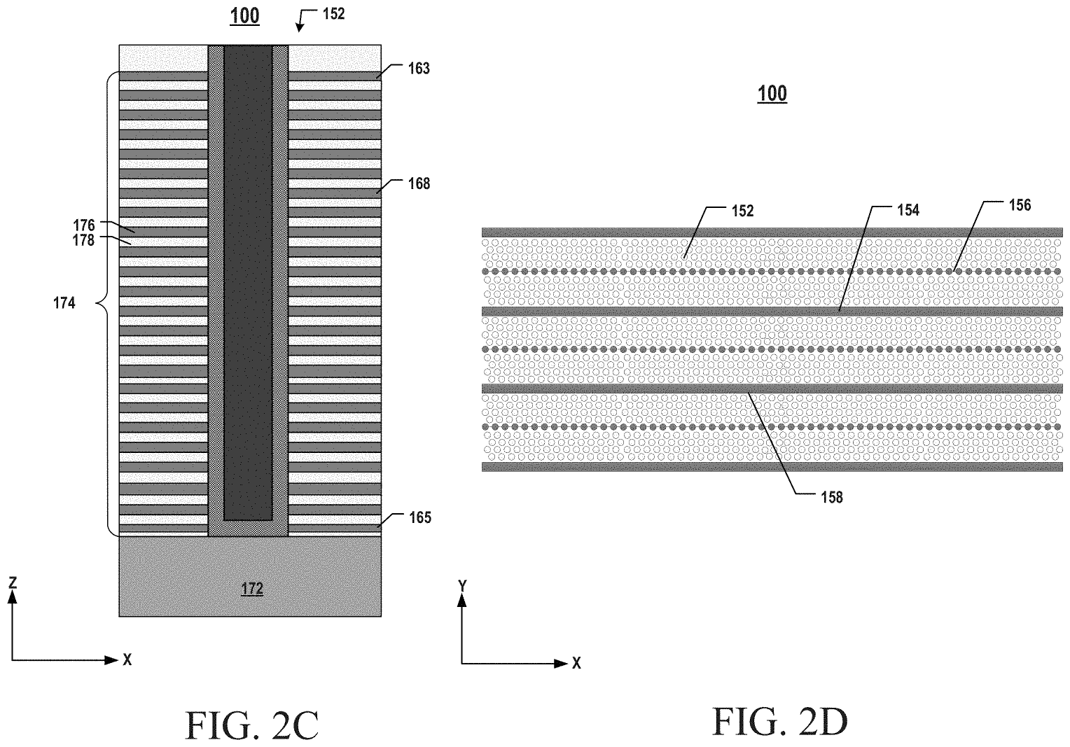

FIG. 2A is a top-view diagram illustrating a NAND string according to an implementation of the present disclosure. FIG. 2B is a diagram illustrating an equivalent circuit thereof. In a flash memory system using the NAND structure, multiple memory cells, each including transistors, are arranged in series and sandwiched between two select gates, which are referred to as a NAND string. The NAND string depicted in FIGS. 2A and 2B includes four memory cells 101˜104 coupled in series and sandwiched between a top select gate SG_T (on the drain side) and a bottom select gate SG_B (on the source side). The top select gate SG_T is arranged for connecting the NAND string to a bit line via a bit line contact and may be controlled by applying appropriate voltages to a select gate line SGTL. The bottom select gate SG_B is arranged for connecting the NAND string to a source line and may be controlled by applying appropriate voltages to a select gate line SGBL. Each of the memory cells 101˜104 includes a control gate and a floating gate. For example, the memory cell 101 includes a control gate CG1 and a floating gate the memory cell 102 includes a control gate CG2 and a floating gate FG2, the memory cell 103 includes a control gate CG3 and a floating gate FG3, and the memory cell 104 includes a control gate CG4 and a floating gate FG4. The control gate CG1 is connected to a word line WU, the control gate CG2 is connected to a word line WL2, the control gate CG3 is connected to a word line WU, and the control gate CG4 is connected to a word line WL4.

For illustrative purposes, FIGS. 2A and 2B show four memory cells in the NAND string. In other implementations, a NAND string may include 8 memory cells, 16 memory cells, 32 memory cells, 64 memory cells, 128 memory cells, etc. However, the number of memory cells in a NAND string does not limit the scope of the present disclosure.

A typical architecture for a flash memory system using a NAND structure includes several NAND strings. Each NAND string is connected to the source line by its bottom select gate SG_B controlled by the select line SGBL and connected to its associated bit line by its top select gate SG_T controlled by the select line SGTL. Each bit line and the respective NAND string(s) that are connected to that bit line via a bit line contact comprise the columns of the array of memory cells. Bit lines are shared with multiple NAND strings. Typically, the bit line runs on top of the NAND strings in a direction perpendicular to the word lines and is connected to one or more sense amplifiers.

FIG. 2C illustrates a side view of a cross-section of an exemplary 3D memory device 100 including NAND memory string 152 according to an implementation of the present disclosure. As shown in FIG. 2C, NAND memory string 152 can extend vertically through a memory stack 174 above a substrate 172. Substrate 172 can include silicon (e.g., single crystalline silicon), silicon germanium (SiGe), gallium arsenide (GaAs), germanium (Ge), silicon on insulator (SOI), germanium on insulator (GOI), or any other suitable materials.

Memory stack 174 can include interleaved gate conductive layers 176 and gate-to-gate dielectric layers 178. The number of the pairs of gate conductive layers 176 and gate-to-gate dielectric layers 178 in memory stack 174 can determine the number of memory cells in the memory cell array. Gate conductive layer 176 can include conductive materials including, but not limited to, tungsten (W), cobalt (Co), copper (Cu), aluminum (Al), polysilicon, doped silicon, silicides, or any combination thereof. In some implementations, each gate conductive layer 176 includes a metal layer, such as a tungsten layer. In some implementations, each gate conductive layer 176 includes a doped polysilicon layer. Each gate conductive layer 176 can include control gates surrounding the memory cells.

As shown in FIG. 2C, NAND memory string 152 includes a channel structure extending vertically through memory stack 174. In some implementations, the channel structure includes a channel hole filled with semiconductor material(s) (e.g., as a semiconductor channel) and dielectric material(s) (e.g., as a memory film). It is understood that although not shown in FIG. 2C, additional components of the memory cell array can be formed including, but not limited to, gate line slits/source contacts, local contacts, interconnect layers, etc.

FIG. 2D illustrates a plan view of an exemplary 3D memory device 100 according to an implementation of the present disclosure, 3D memory device 100 includes an array of NAND memory strings 152 and multiple parallel gate line slits (GLSs) 154, which divide array of NAND memory strings 152 into different memory regions (e.g., memory blocks). 3D memory device 100 also includes multiple parallel TSG cuts 156 that separate the electrical connections between TSGs of NAND memory strings 152 in different regions. As shown in FIG. 2D, each GLS 154 and TSG cut 156 extends laterally along the word line direction in a straight-line pattern in the plan view (parallel to the wafer plane). It is noted that x and y axes are included in FIG. 2D to illustrate two orthogonal directions in the wafer plane. The x-direction is the word line direction, and the y-direction is the bit line direction.

Etching of GLSs 154 and TSG cuts 156 can result in a large number of parallel trenches in the x-direction, which can cause a substantial change of wafer how and/or warpage in the x-direction, but not in the y-direction.

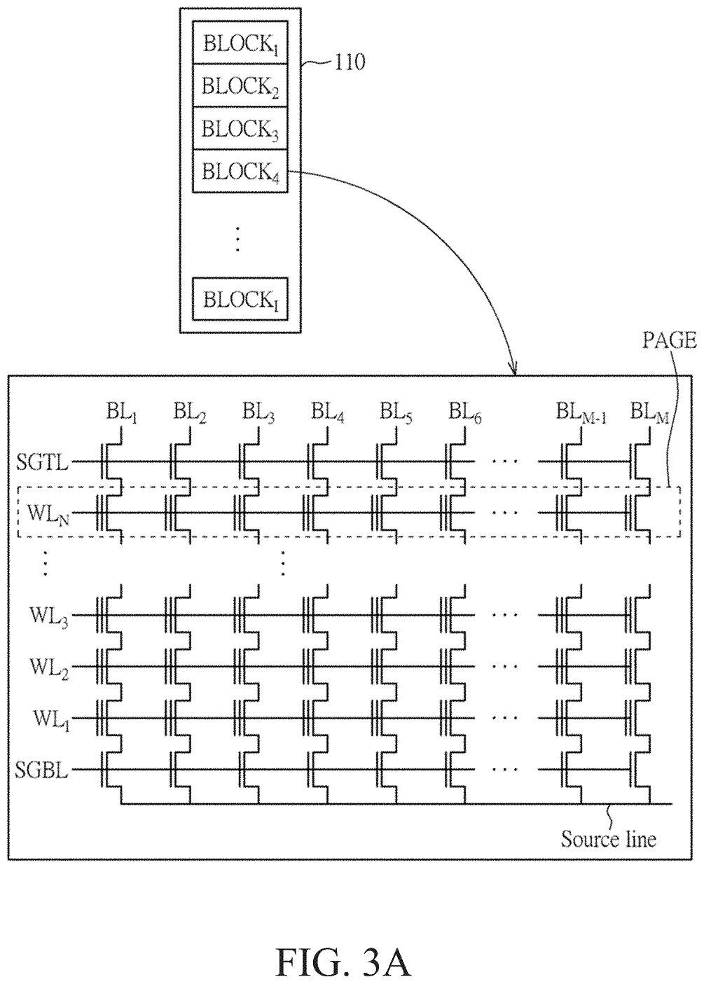

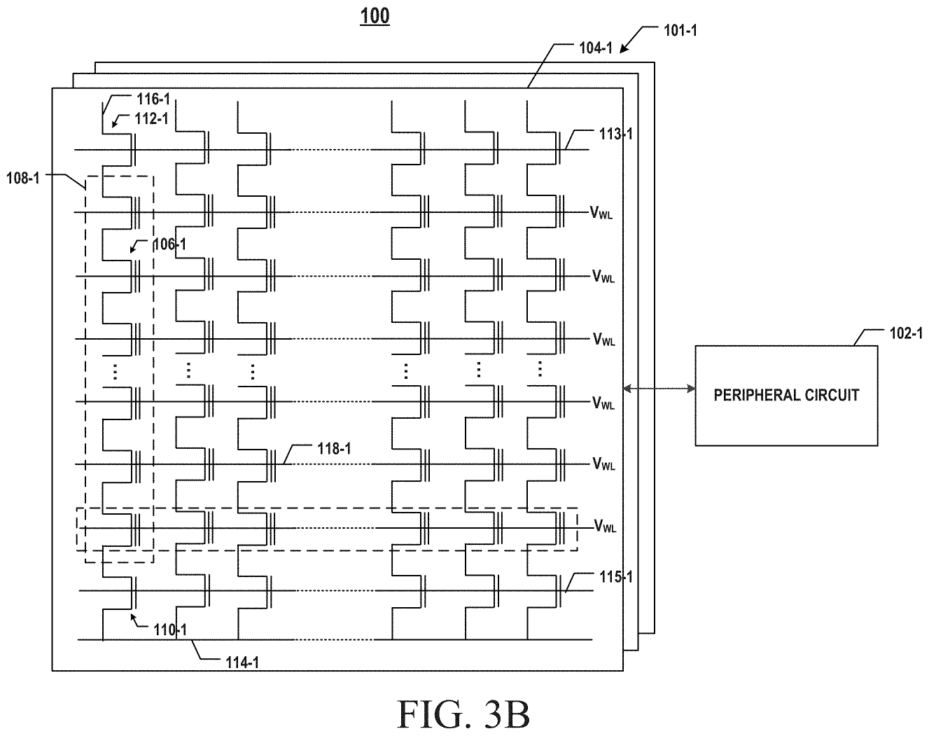

FIG. 3A is a diagram illustrating an exemplary structure of a memory cell array 110 according to an implementation of the present disclosure. The memory cell array 110 is divided into multiple blocks of memory cells denoted by BLOCK₁˜BLOCK₁, wherein I is a positive integer and typically equal to a large number. A block contains a set of NAND strings which are accessed via bit lines BL₁˜BL_{M} and a common set of word lines WL₁˜WL_{N}, wherein M and N are integers larger than 1. One terminal of the NAND string is connected to a corresponding bit line via the top select gate (connected to the select gate line SGTL), and another terminal is connected to the source line via the bottom select gate (connected to select gate line SGBL).

FIG. 3B illustrates a schematic circuit diagram of a memory device 100 including peripheral circuits, according to some aspects of the present disclosure. Memory device 100 can include a memory cell array 101-1 and peripheral circuits 102-1 coupled to memory cell array 101-1. Memory cell array 101-1 can be a NAND Flash memory cell array in which memory cells 106-1 are provided in the firm of an array of 3D NAND memory strings 108-1 each extending vertically above a substrate (not shown). In some implementations, each 3D NAND memory string 108-1 includes a plurality of memory cells 106-1 coupled in series and stacked vertically. Each memory cell 106-1 can hold a continuous, analog value, such as an electrical voltage or charge, that depends on the number of electrons trapped within a region of memory cell 106-1. Each memory cell 106-1 can be either a floating gate type of memory cell including a floating-gate transistor or a charge trap type of memory cell including a charge-trap transistor. Each array of 3D NAND memory strings 108-1 can include one or more 3D memory devices.

In some implementations, each memory cell 106-1 is a single-level cell (SLC) that has two possible memory states and thus, can store one bit of data. For example, the first memory state “0” can correspond to a first range of voltages, and the second memory state “1” can correspond to a second range of voltages. In some implementations, each memory cell 106-1 is a multi-level cell (MLC) that is capable of storing more than a single bit of data in four or more memory states. For example, the MLC can store two bits per cell, three bits per cell (also known as triple-level cell (TLC)), or four bits per cell (also known as a quad-level cell (QLC)). Each MLC can be programmed to assume a range of possible nominal storage values. In one example, if each MLC stores two bits of data, then the MLC can be programmed to assume one of three possible programming levels from an erased state by writing one of three possible nominal storage values to the cell. A fourth nominal storage value can be used for the erased state.

As shown in FIG. 3B, each 3D NAND memory string 108-1 can include a source select gate (SSG) transistor 110-1 at its source end and a drain select gate (DSG) transistor 112-1 at its drain end. SSG transistor 110-1 and DSG transistor 112-1 can be configured to activate selected 3D NAND memory strings 108-1 (columns of the array) during read and program operations. In some implementations, the sources of SSG transistors 110-1 of 3D NAND memory strings 108-1 in the same block 104-1 are coupled through a same source line (SL) 114-1, e.g., a common SL, for example, to the ground. DSG transistor 112-1 of each 3D NAND memory string 108-1 is coupled to a respective bit line 116-1 from which data can be read or programmed via an output bus (not shown), according to some implementations. In some implementations, each 3D NAND memory string 108-1 is configured to be selected or unselected by applying a select signal (e.g., a select voltage above the threshold voltage of DSG transistor 112-1) or a deselect signal (e.g., a deselect voltage such as 0 V) to respective DSG transistor 112-1 through one or more DSG lines 113-1 and/or by applying a select voltage (e.g., above the threshold voltage of SSG transistor 110-1) or a deselect voltage (e.g., 0 V) to respective SSG transistor 110-1 through one or more SSG lines 115-1.

As shown in FIG. 3B, 3D NAND memory strings 108-1 (e.g., may correspond to 152 in FIGS. 2C and 2D) can be organized into multiple blocks 104-1, each of which can have a common source line 114-1. In some implementations, each block 104-1 is the basic data unit for erase operations, i.e., all memory cells 106-1 on the same block 104-1 are erased at the same time. Memory cells 106-1 can be coupled through word lines 118-1 that select which row of memory cells 106-1 is affected by read and program operations. In some implementations, each word line 118-1 is coupled to a row of memory cells 106-1, which is the basic data unit for program and read operations. Each word line 118-1 can be coupled to a plurality of control gates (gate electrodes) at each memory cell 106-1 in respective row and a gate line coupling the control gates.

Peripheral circuits 102-1 can be coupled to memory cell array 101-1 through bit lines 116-1, word lines 118-1, source lines 114-1, SSG lines 115-1, and DSG lines 113-1. As described above, peripheral circuits 102-1 can include any suitable circuits for facilitating the operations of memory cell array 101-1 by applying and sensing voltage signals and/or current signals through bit lines 116-1 to and from each target memory cell 106-1 through word lines 118-1, source lines 114-1, SSG lines 115-1, and DSG lines 113-1. Peripheral circuits 102-1 can include various types of peripheral circuits formed using complementary metal-oxide semiconductor (CMOS) technologies.

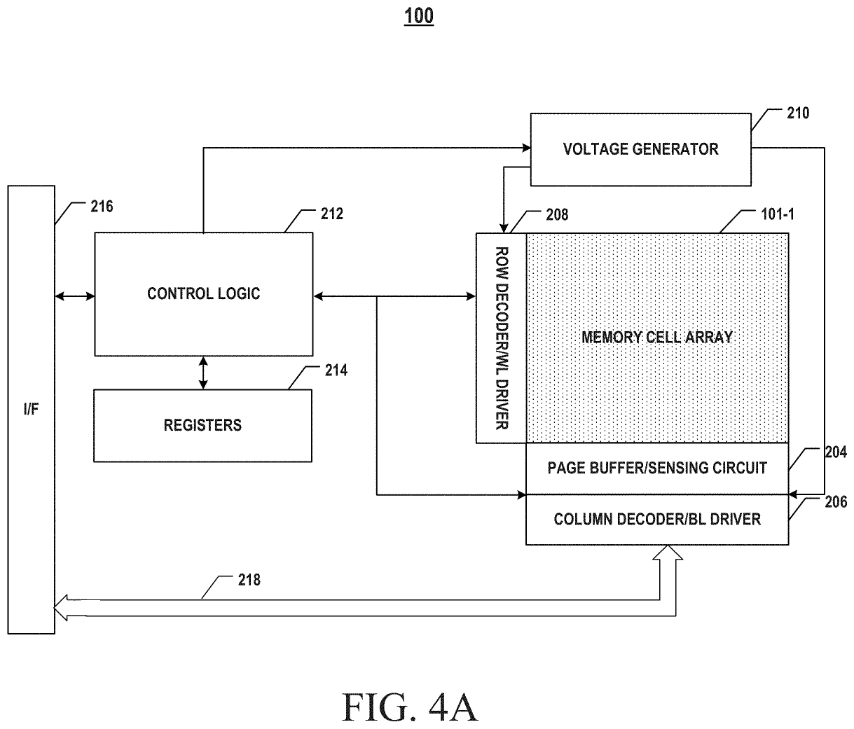

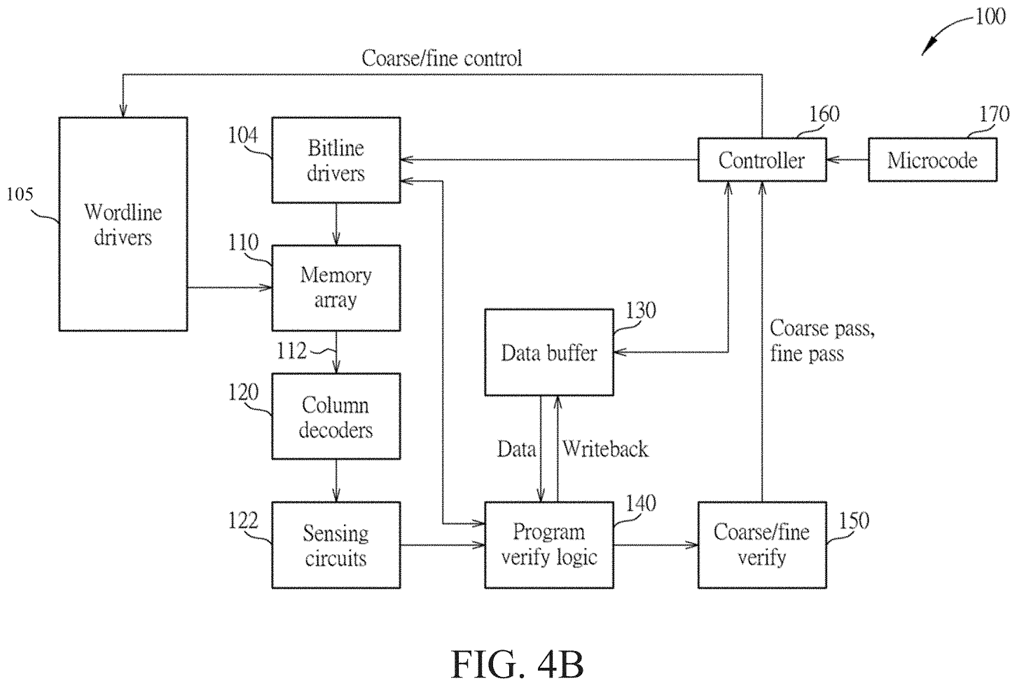

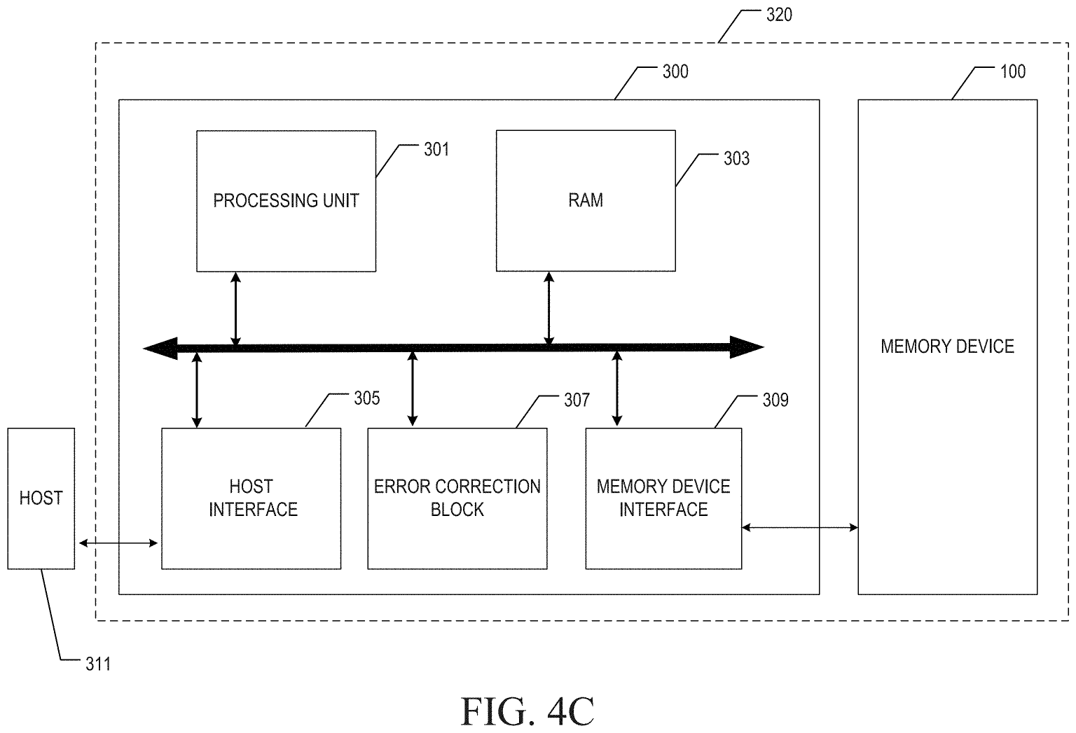

For example, FIG. 4A illustrates some exemplary peripheral circuits 102-1 including a page buffer 204, a column decoder/bit line driver 206, a row decoder/word line driver 208, a voltage generator 210, control logic 212, registers 214, an interface (I/F) 216, and a data bus 218. It is understood that in some examples, additional peripheral circuits 102-1 may be included as well.

Page buffer 204 can be configured to buffer data read from or programmed to a memory cell array, e.g., memory cell array 110 in FIG. 3A or memory cell array 101-1 in FIG. 3B, according to the control signals of control logic 212. It is noted that the following memory cell array uses memory cell array 101-1 in FIG. 3B for illustration hereinafter, while it can also the memory cell array 110 in FIG. 3A, or other implementations of the memory cell array. For example, page buffer 204 may store one page of program data (write data) to be programmed into one row of memory cell array 101-1. In another example, page buffer 204 also performs program verify operations to ensure that the data has been properly programmed into memory cells 106-1 coupled to selected word lines 118-1.

Row decoder/word line driver 208 can be configured to be controlled by control logic 212 and select or unselect a block 104-1 of memory cell array 101-1 and select or unselect word line 118-1 of selected block 104-1. Row decoder/word line driver 208 can be further configured to drive memory cell array 101-1. For example, row decoder/word line driver 208 may drive memory cells 106-1 coupled to the selected word line 118-1 using a word line voltage generated from voltage generator 210. In some implementations, row decoder/word line driver 208 can include a decoder and string drivers (driving transistors) coupled to local word lines and word lines 118-1.

Voltage generator 210 can be configured to be controlled by control logic 212 and generate the word line voltages (e.g., read voltage, program voltage, pass voltage, local voltage, and verification voltage) to be supplied to memory cell array 101-1. In some implementations, voltage generator 210 is part of a voltage source that provides voltages at various levels of different peripheral circuits 102-1 as described below in detail. Consistent with the scope of the present disclosure, in some implementations, the voltages provided by voltage generator 210, for example, to row decoder/word line driver 208 and page buffer 204 are above certain levels that are sufficient to perform the memory operations. For example, the voltages provided to page buffer 204 may be between 2 V and 3.3 V, such as 3.3 V, and the voltages provided to row decoder/word line driver 208 may be greater than 3.3 V, such as between 3.3 V and 30 V.

Column decoder/bit line driver 206 can be configured to be controlled by control logic 212 and select one or more 3D NAND memory strings 108-1 by applying bit line voltages generated from voltage generator 210. For example, column decoder/hit line driver 206 may apply column signals for selecting a set of N bits of data from page buffer 204 to be outputted in a read operation.

Control logic 212 can be coupled to each peripheral circuit 102-1 and configured to control operations of peripheral circuits 102-1. Registers 214 can be coupled to control logic 212 and include status registers, command registers, and address registers for storing status information, command operation codes (OP codes), and command addresses for controlling the operations of each peripheral circuit 102-1.

Interface 216 can be coupled to control logic 212 and configured to interface memory cell array 101-1 with a memory controller (not shown). In some implementations, interface 216 acts as a control buffer to buffer and relay control commands received from the memory controller and/or a host (not shown) to control logic 212 and status information received from control logic 212 to the memory controller and/or the host. Interface 216 can also be coupled to page buffer 204 and column decoder/bit line driver 206 via data bus 218 and act as an Input/Output (I/O) interface and a data buffer to buffer and relay the program data received from the memory controller and/or the host to page buffer 204 and the read data from page buffer 204 to the memory controller and/or the host. In some implementations, interface 216 and data bus 218 are part of an I/O circuit of peripheral circuits 102-1.

FIG. 4B is a block diagram of a memory device 100 according to an implementation of the present disclosure. The memory device 100 includes a memory cell array 110 (in some implementations, it can also be the memory cell array 101-1 in FIG. 3B), word line drivers 105, bit line drivers 104, column decoders 120, sensing circuits 122, a data buffer 130, a program verify logic 140, a coarse/fine verify circuit 150, a controller 160, and a microcode 170. The memory cell array is a nonvolatile memory cell array that maintains its state when power is removed. For example, the memory cell array may be a NAND flash memory that includes memory cells having floating gate transistors as depicted in FIGS. 1 and 2, or as depicted in FIGS. 3A and 3B. Also, the memory cell array may be laid in a 3D MLC structure in order to increase data capacity. However, the type of memory device 100 does not limit the scope of the present disclosure.

Memory device 100 may include functional blocks and signal lines not shown in FIG. 3A or 3B. For example, memory device 100 may include a write interface circuit or a read interface circuit that couples various portions of the memory device 100 to an external bus. Further, memory device 100 may include signal lines from one or more interface circuits to the controller 160, the data buffer 130, or any other block shown in FIG. 3A or 3B. The blocks that are shown in FIG. 3A or 3B were chosen to support an explanation of various implementations relating to the programming of the memory cell array 110 in FIG. 3A or the memory cell array 101-1 in FIG. 3B.

Controller 160 may be any type of suitable controller capable of effecting programming operations within memory device 100. For example, controller 160 may be an embedded microprocessor, a microcontroller, or the like. In operation, controller 160 is configured to receive and execute software instructions from microcode 170. Microcode 170 may be held in a nonvolatile memory element, such as a separate flash memory. However, the manner in which processor 160 and microcode 170 are implemented does not limit the scope of the present disclosure.

When programming memory cell array 110, data to be programmed is placed in data buffer 130. In some implementations, data to be programmed may be placed in data buffer 130 by controller 160. Further, a programming operation may program a subset of memory cell array 110, and data buffer 130 may only hold data to program the subset. During a programming operation, bit line drivers 104 are configured to supply appropriate voltages to the bit lines within memory cell array 110, and word line drivers 105 are configured to provide programming pulses on the word lines within memory cell array 110.

In some implementations, the memory cell array 110 is a NAND flash memory that includes an array of multilevel memory cells. For example, the memory cell array 110 laid in a multi-level cell (MLC) structure can store 2 bits per cell, the memory cell array 110 laid in a triple-level cell (TLC) structure can store 3 bits per cell, and the memory cell array 110 laid in a quad-level cell (QLC) structure can store 4 bits per cell.

Using the MLC structure for illustrative purposes, each multilevel cell may support four different program states represented by different threshold voltages on a floating gate transistor. These four states may be represented as level zero (L0), level one (L1), level two (L2), and level three (L3), where L0 corresponds to an unprogrammed memory cell with a lowest threshold voltage, L3 corresponds to a programmed memory cell with a highest threshold voltage, and L1 and L2 correspond to programmed memory cells with intermediate threshold voltages. L3, L2, L1, and L0 are also represented as “00,” “01,” “10,” and “II,” respectively.

In the MLC implementation, the data buffer 130 is loaded with values in pairs to be programmed into the memory cell array HO. For example, because each MLC memory cell may be programmed with two bits of information, the data buffer 130 is loaded with data bits in pairs that represent levels L0, L1, L2, and L3. Since the bits held by the memory cells to be erased are all ones, the MLC memory cells that are to be programmed with L0, or “11,” need not be programmed at all. The various implementations of the present disclosure recognize that the cells that are to hold “11” need not be programmed, that cells that are to hold “00” may be programmed to a high threshold voltage, and that cells that are to hold “10” or “01” may be programmed to intermediate threshold voltages. The threshold voltages corresponding, to the various programmed states are defined to be a sufficient distance from each other so as to allow reliable reading of the MLC memory cells.

In some implementations, the memory device 100 supports programming MLC cells within memory cell array 110 using multiple pulses on the word lines where the pulses are at different voltages. Further, the memory device 100 supports incrementing gate voltages on the word lines in coarse steps until the programmed values approach the desired intermediate threshold voltages, and then continuing to increment gate voltages on the word lines in fine steps until the programmed values meet or exceed a pre-determined level. Various programming implementations utilizing coarse and fine word line voltage steps are described further below. As used herein, the term “coarse pulse” refers to a programming pulse that is applied after a coarse step in word line voltage, and the term “fine pulse” refers to a programming pulse that is applied after a fine step in word line voltage.

During programming, the controller 160 or the control logic 212 is configured to instruct the bit line drivers 104 or the bit line drivers 206 to provide appropriate voltages to the bit lines and instruct voltage generator 210 to provide coarse and fine gate voltages through the word line drivers 105 or the word line drivers 208 to the word lines of the memory cell array.

In some implementations, the word line drivers 105 provide a “verify voltage” on the word lines between programming operations to perform a “verify” operation. Various implementations of the present disclosure utilize two different types of verify operations: “coarse verify” and “fine verify.” Coarse verify and fine verify are described further below.

During a coarse verify (after a coarse pulse) or during a fine verify (after a fine pulse), the column decoders 120 (e.g., may correspond to column decoder 206 in FIG. 4A) are configured to receive data from the sensing circuits 122 (e.g., may correspond to page buffer 204 in FIG. 4A). The sensing circuits 122 may include one or more reference circuits that provide reference levels to which the data may be compared. For example, the data may be in the form of a current, and the reference circuits may include programmed memory cells that provide reference currents. In some implementations, multiple references exist for each level. Using the MLC implementation for illustrative purposes, the sensing circuits 122 may include an L1 coarse reference, an L1 fine verify current, an L2 verify current, an L2 fine verify current, and an L3 verify current.

For example, during a coarse verify, the sensing circuits 122 generate digital output signals by comparing the output of the column decoders 120 with a coarse verify current, and these digital output signals are compared to the data in the data buffer 130. In some implementations, multiple locations within the memory cell array 110 are programmed simultaneously, and during a verify operation, multiple locations within the memory cell array 110 are verified simultaneously. For example, 32 locations within memory cell array 110 are verified simultaneously. Further, in some implementations, the number of locations programmed simultaneously within the memory cell array 110 may be variable based on the communication bandwidth of various buses, or the current capability of a program pump within the memory device 100.

During a coarse verify operation, detect if any of the memory cells being programmed has exceeded the corresponding coarse reference, and if so, assert the “coarse pass” signal to the controller 160. Using the MLC implementation for illustrative purposes, a coarse verify operation is performed on all memory cells currently being programmed with either L1 or L2. In these implementations, if even one memory cell exceeds the corresponding coarse reference, the coarse pass signal will be asserted. By asserting the coarse pass signal, controller 160 is informed to switch from coarse gate voltage steps to fine gate voltage steps.

After receiving a coarse pass signal, the controller 160 is configured to instruct the word line drivers 105 to provide fine gate voltage steps on the word lines within the memory cell array 110 via the voltage generator (e.g., voltage generator 210 in FIG. 4A′. During a fine verify operation (after a fine pulse), the sensing circuits 122 may compare the output of the column decoders 120 with corresponding fine verify current. Using the MLC implementation for illustrative purposes, data in a location being programmed with L1 is compared to an L1 fine verify current, and data in a location being programmed with L2 is compared to an L2 fine verify current. Also, during a fine verify operation, the program verify logic 140 may compare the output of sensing circuits 122 and data from data buffer 130. For locations that meet or exceed the corresponding fine verify current, the program verify logic 140 is configured to writes a pass data, such as “11,” in the data buffer 130 for indicating that a corresponding memory cell has passed the fine verify operation. For locations that do not meet or exceed the corresponding fine verify current, the program verify logic 140 does not change the data in the data buffer 130. Fine pulses are then repeated, but not for those locations that have met or exceeded the fine verify current because the data in data buffer 130 corresponding to those locations is now “11.” The “fine pass” signal is asserted only when all memory cells being programmed have been programmed correctly.

FIG. 4C is a block diagram of a memory system 320 including a memory controller according to an implementation of the present disclosure. The memory system may include a memory device 100, a memory controller 300 coupled to memory device 100, and a host 311 coupled to memory controller 300.

Memory controller 300 is configured to operate memory device 100 at the request of host 311. In some implementations, memory controller 300 is configured to control a read operation, a program operation, an erase operation, or other operations of memory device 100. Memory controller 300 may include an interface between memory device 100 and host 311. Memory controller 300 is configured to drive firmware for controlling the operations of memory device 100.

Memory controller 300 may include a random access memory (RAM) 303, a processing unit 301, a host interlace 305, a memory interface 309, and an error correction block 307.

RAM 303 is configured to be used as an operation memory of processing unit 301, a cache memory between memory device 100 and host 311, or a buffer memory between memory device 100 and host 311.

Processing unit 301 is configured to control operations of memory controller 300. Processing unit 301 is configured to control a read operation, a program operation, an erase operation, or other operations of memory device 100. In some implementations, processing unit 301 may function as a flash translation layer (FTL). Processing unit 301 may translate a logical block address (LBA) provided by host 311 into a physical block address (PBA) through the FTL. The FTL may receive the LBA by using a logical to physical (L2P) mapping table and translate the LBA into the PBA. There may be various address mapping methods for the flash translation layer according to a mapping unit. Examples of these address mapping methods may include a page mapping method, a block mapping method, and a hybrid mapping method. Processing unit 301 may be configured to execute the methods or the operations according to the implementations of the present disclosure.

Host interface 305 may include a protocol for data exchange between host 311 and memory controller 300. In some implementations, memory controller 300 may communicate with host 311 using at least one of a variety of interface protocols, such as a universal serial bus (USB) protocol, a multimedia card (MMC) protocol, a peripheral component interconnection (PCI) protocol, a PCI-Express (PCI-E) protocol, an advanced technology attachment (ATA) protocol, a. Serial-ATA protocol, a Parallel-ATA protocol, a small computer small interface (SCSI) protocol, an enhanced small disk interface (ESDI) protocol, an integrated drive electronics (IDE) protocol, and a private protocol.

Memory interface 309 may interface with memory device 100. For example, memory interface 100 may include a NAND flash interface or a NOR flash interface.

Error correction block 307 may detect and correct an error in data received from memory device 100 by using an error correction code (ECC). In addition, error correction block 307 may correct an error in the read page data by using the ECC.

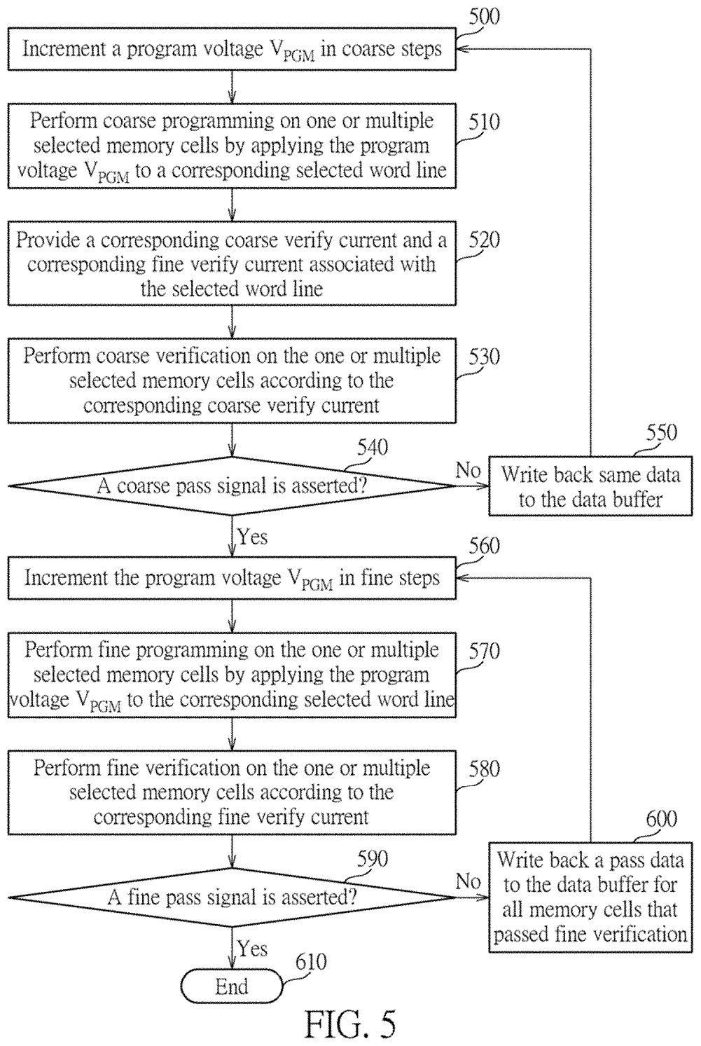

FIG. 5 is a flowchart illustrating a method of programming and verifying the memory cell array memory cell array 110 or memory cell array 101-1) in memory device 100 according to an implementation of the present disclosure. The flowchart in FIG. 5 includes the following steps:

Step 500: increment a program voltage V_{PGM} in coarse steps.

Step 510: perform coarse programming on one or multiple selected memory cells by applying the program voltage V_{PGM} to a corresponding selected word line.

Step 520: provide a corresponding coarse verify current and a corresponding fine verify current associated with the selected word line.

Step 530: perform coarse verification on the one or multiple selected memory cells according to the corresponding coarse verify current.

Step 540: determine whether a coarse pass signal is asserted; if yes, execute step 560; if not, execute step 550.

Step 550: write back same data to the data buffer; execute step 500.

Step 560: increment the program voltage V_{PGM} in fine steps.

Step 570: perform fine programming on the one or multiple selected memory cells by applying the program voltage V_{PGM} to the corresponding selected word line.

Step 580: perform fine verification on the one or multiple selected memory cells according to the corresponding fine verify current.

Step 590: determine whether a fine pass signal is asserted; if yes, execute step 610; if not, execute step 600.

Step 600: write back a pass data to the data buffer for all memory cells that passed fine verification; execute step 610.

Step 610: end.

In steps 500 and 560, the controller 160 or the control logic 212 is configured to instruct the word line drivers 105 or the word line drivers 208 to apply the programming voltage V_{PGM} generated by voltage generator 210 which may be a series of programming voltage pulses in the form of a staircase waveform starting from an initial voltage level. The memory cell under programming is subject to this series of programming voltage pulses, with an attempt each time to add incremental charges to its floating gate.

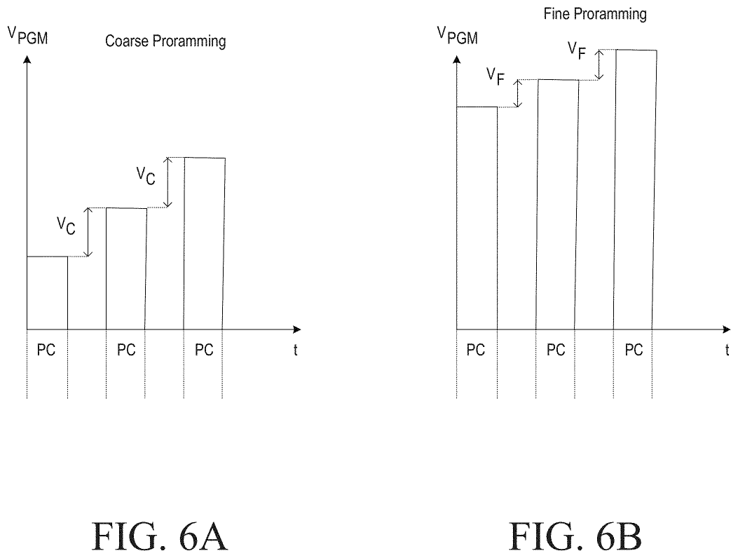

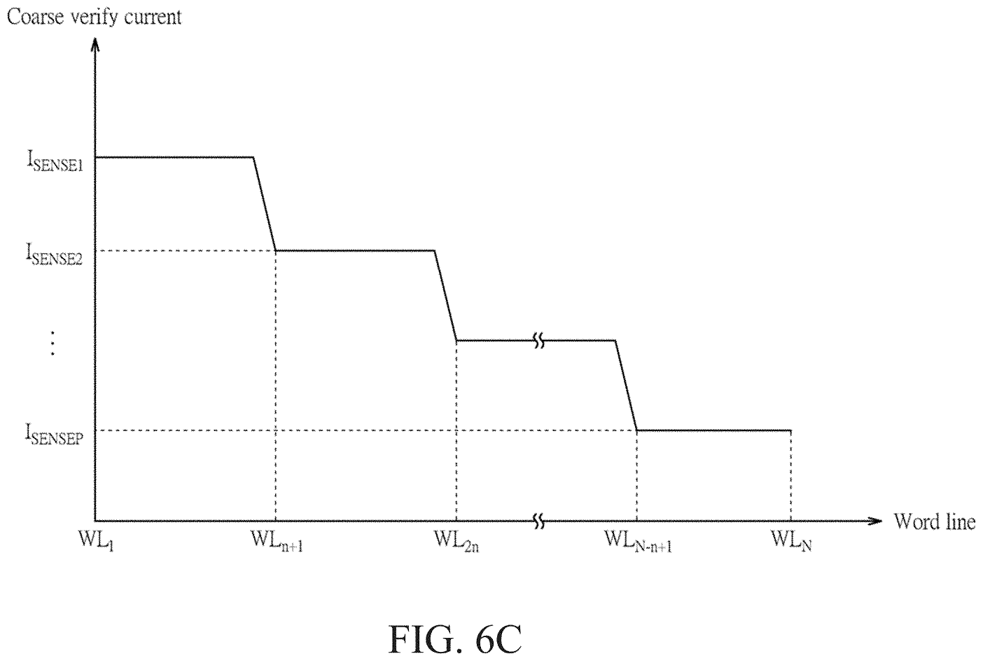

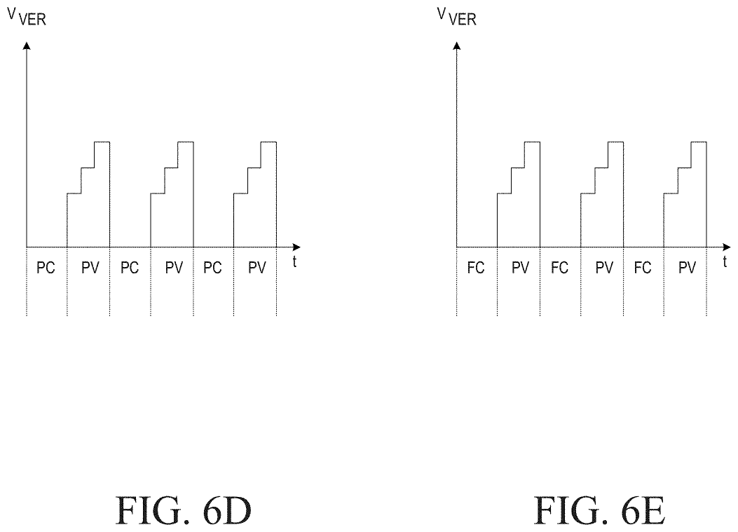

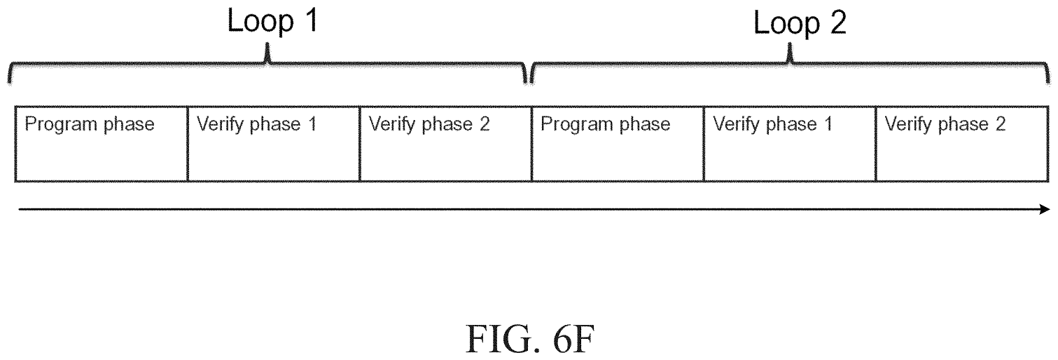

FIGS. 6A and 6B are diagrams illustrating the waveform of the programming voltage V_{PGM} when executing steps 500 and 560 according to an implementation of the present disclosure. In step 500, the programming voltage V_{PGM} is incremented in coarse steps during each coarse program period PC. More specially, the level of the programming voltage V_{PGM} is incremented by an amount of V_{C} (coarse pulses) at the start of each coarse program period PC. In step 560, the programming voltage V_{PGM} is incremented in fine steps during the program periods PF1. More specially, the level of the programming voltage V_{PGM} is incremented by an amount of Y_{F} (fine pulses) at the start of each fine program period FC, wherein V_{F}<V_{C}. In some implementations, the voltage pulses of coarse program and the voltage pulses of fine program are independent. And the coarse program and the fine program applied to a same word line may or may not be performed continuously. For example, in some implementations, it can be a coarse program of WLn, a fine program of WLn−1, a coarse program of WLn+1, a fine program of WLn, and a coarse program of WLn+2 performed in sequence. It is noted that the voltage pulses of a coarse program are larger than the voltage pulses of a fine program during a same target program state.

In step 510, coarse programming may be performed on one or multiple selected memory cells by applying the program voltage V_{PGM} (coarse pulses) to a corresponding selected word line during one or multiple coarse program period PC. In step 570, fine programming may be performed on one or multiple selected memory cells by applying the program voltage V_{PGM} (fine pulses) to a corresponding selected word line during one or multiple fine program period FC. Each pulse adds incremental charges to the one or multiple selected memory cells with a goal to reach one or multiple program states stored in the data buffer 130 or the page buffer 204.

In step 520, the sensing circuits 122 may include one or more reference circuits that provide reference levels based on which coarse verification and fine verification may be conducted. For example, the data may be in the form of a current, and the reference circuits may include programmed memory cells that provide reference currents. In some implementations, multiple references exist for each programmed level. Using the MLC implementation for illustrative purposes, the sensing circuits 122 may provide an L1 coarse verify current, an L1 fine verify current, an L2 coarse verify current, an L2 fine verify current, and an L3 verify current.

To address the above-mentioned issues, under BOC and WOC program scenarios, different coarse verify currents may be provided so as to keep the ΔV—a voltage difference between fine verify operation and coarse verify operation, as constant. In the present disclosure, the value of each coarse verify current may be adjusted according to the sequence of programming the word lines.

In some implementations, the common set of word lines WL₁˜WL_{N} is further grouped in P word line subsets SUB₁˜SUB_{P}, wherein each word line subset includes n adjacent word lines (n is a positive integer smaller than N). First, the word lines in the first word line subset SUB₁ are sequentially programmed, followed by sequentially programming the word lines WLₙ₊₁˜WL₂ₙ, in the second word line subset SUB₂. The same procedure continues until the word lines WL_{N-n+1}˜WL_{N} in the P^{th} word line subset are sequentially programmed.

In one example, word lines WL₁˜WL_{N} is grouped in Q word line subsets SUB₁˜SUB_{Q}, wherein each word line subset is defined by sense-out (SO) node development time—a period of time determined by discharging SO node capacitor corresponding to the selected bit line to a specific voltage. Specifically, a first word line subsets SUB₁˜SUB_{X} are defined by a first range of SO node development time, a second word line subsets SUB_{X+1}˜SUB_{Y} are defined by a second range of SO node development time, and a third word line subsets SUB_{Y+1}˜SUB_{Q} are defined by a third range of SO node development time, where X, Y, and Q are integers. In some implementations, first word line subsets SUB₁˜SUB_{X}, second word line subsets SUB_{X+1}˜SUB_{Y}, and third word line subsets SUB_{Y}+˜SUB_{Q} are programmed sequentially, and a first range of SO node development time, a second range of SO node development time, and a third range of SO node development time increase sequentially. That is, the earlier programmed word line subsets are defined by smaller SO node development time, while the later programmed word line subsets are defined by larger SO node development time. In some implementations, each word line subset defined by SO node development time can be further defined by a formula: I_coarse_sense=C_so*ΔV_so/t_sodev_coarse, where I_coarse_sense is the coarse verify current, C_so is the capacitor connected to the SO node (e.g., an SO node capacitor), ΔV_so is a voltage difference between fine verify operation and coarse verify operation in the SO node, and t_sodev_coarse is the SO node development time during the coarse verify operation. Since smaller SO node development time t_sodev_coarse means larger coarse verify current I_coarse_sense according to the above formula, the earlier programmed word line subsets are verified by larger coarse verify current, while the later programmed word line subsets are verified by smaller coarse verify current.

In some implementations, for example, by adapting the smaller coarse verify current during a lower temperature program (e.g., in a same word line or in a different word line), the ΔV can be kept constant. As such, by compensating lower temperature program with smaller coarse verify current, the ΔV can be kept constant.

In one example, for a same program state, compensating the same programmed word line with lower temperature with a smaller coarse verify current can be done by enlarging the SO node development time, while compensating the same programmed word line with higher temperature with a larger coarse verify current can be done by reducing the SO node development time. It is noted that the temperature herein may include a local ambient temperature (i.e., the temperature of the surrounding air or environment in which the memory device resides) sensed by a temperature sensor in at least a circuit of the memory device. The lower the temperature is, the higher the SO development time can be achieved, and vice versa.

In another example, for a same program state, compensating the same programmed word line with lower temperature with a smaller coarse verify current can be done by enlarging the bias voltage applied on the selected word line, while compensating the same programmed word line with higher temperature with a larger coarse verify current can be done by reducing the bias voltage applied on the selected word line.

FIG. 6C is a diagram illustrating the value of the coarse verify current associated with each word line subset. As depicted, if a selected memory cell controlled by a word line in the first word line subset SUB₁ is to be programmed to L1, the corresponding coarse verify current is set to I_{SENSE1}; if a selected memory cell controlled by a word line in the second word line subset SUB₂ is to be programmed to L1, the corresponding coarse verify current is set to I_{SENSE2}; . . . ; if a selected memory cell controlled by a word line in the P^{th} word line subset SUB_{P} is to be programmed to L1, the corresponding coarse verify current is set to I_{SENSEP}, wherein I_{SENSE1}>I_{SENSE2}> . . . >I_{SENSEP}. In other words, the coarse verify current associated with a word line subset which has been programmed to L1 at a later time is set to a smaller value than the coarse verify current associated with a word line subset which has been programmed to L1 at an earlier time.

In steps 530 and 580, coarse/fine verification may be performed on the one or multiple selected memory cell by reading back the memory cell. The read back process may involve one or more sensing operations by applying verify voltages V_{VER} in between the programming pulses.

FIGS. 6D and 6E are diagrams illustrating the waveform of the verify voltages V_{VER} when executing steps 530 and 580 according to an implementation of the present disclosure. With reference to FIGS. 6A and 6B, each verify period PV is inserted between two adjacent program periods for confirming the current voltage level of the one or multiple selected memory cell.

In steps 540 and 590, the column decoders 120 may receive data from the memory cell array 110 during each verify period and direct that data to the sensing circuits 122. The sensing circuits 122 (e.g., may correspond to page buffer 204 in FIG. 4A) may compare the data from the memory cell array 110 (or the memory cell array 101-1 in FIGS. 3B and 4A) with the corresponding coarse/fine verify current.

In step 540, if none of the memory cells being programmed has exceeded the corresponding coarse verify current, the program verify circuit 140 (e.g., may be implemented in a part of controller 160 in FIG. 4B, a part of control logic 212 in FIG. 4A, or a part of data buffer 103, or a part of page buffer 204 in FIG. 4A) writes the same data back to the data buffer 130 in step 550. In another implementation, step 550 may be omitted, and the method directly loops back to step 500 after the “no” determination in step 540. The above-mentioned loop aims at adding incremental charges to the one or multiple selected memory cell until at least one of the memory cells being programmed has exceeded the corresponding coarse verify current.

If any of the memory cells being programmed has exceeded the corresponding coarse reference, the coarse/fine verify circuit 150 asserts the “coarse pass” signal to the controller 160, resulting in the “yes” determination in step 540. Using the MLC implementation for illustrative purposes, a coarse verify operation is performed on all memory cells currently being programmed with either L1 or L2. In these implementations, if any memory cell exceeds the corresponding coarse reference, the coarse/fine verify circuit 150 will assert the coarse pass signal. By asserting the coarse pass signal, the coarse/fine verify circuit 150 may inform the controller 160 to increment the program voltage V_{PGM} in fine steps in step 560.

If at least one of the memory cells being programmed has not exceeded the corresponding fine verify current, the fine pass signal is not asserted, resulting in the “no” determination in step 590. Under such a circumstance, the program verify circuit 140 writes the indication data to the data buffer 130 for all memory cells that passed the fine verify (exceeded the corresponding fine verify current) in step 600. Next, the method directly loops back to step 560. The indication data, such as “11” in the MLC configuration, prevents all memory cells that have passed the fine verify to be re-pulsed. The above-mentioned loop aims at adding incremental charges to the one or multiple selected memory cells until all of the memory cells being programmed have exceeded the corresponding fine verify current.

In the present disclosure, coarse and fine programming may be adopted to improve overall programming speed. Also, a coarse/fine verify is performed according to a corresponding coarse/fine verify current after each step of coarse/fine programming to determine whether the selected memory cell has reached a desired value. The value of each coarse verify current may be adjusted according to the sequence of programming the word lines, thereby compensating for the gain variations among different memory cells. Therefore, the present method can provide a large margin on the threshold voltages of the memory cells.

FIG. 6F is a diagram illustrating a sequence of program operations and verify operations in a 3BL program scheme according to an implementation of the present disclosure. For example, in a first loop (e.g., Loop 1), a program operation is performed in a program phase, a first verify operation (e.g., a coarse verify operation) is performed in a first verify phase (e.g., a coarse verify phase) following the program phase, and a second verify operation (e.g., a fine verify operation) is performed in a second verify phase (e.g., a fine verify phase) following the first verify phase.

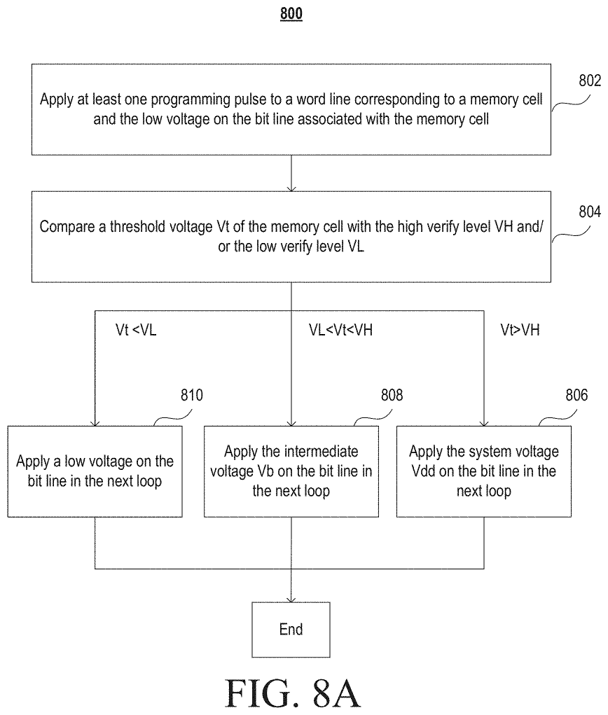

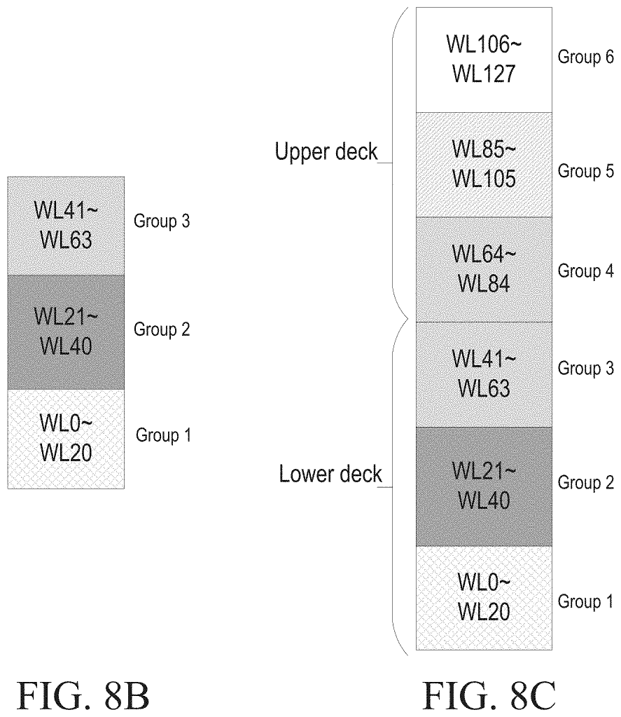

Next, in a next loop (e.g., a second loop, Loop 2), a program operation is performed in a program phase using a result of comparison during the first loop (e.g., Loop1), a first verify operation (e.g., a coarse verify operation) is performed in a first verify phase (e.g., a coarse verify phase) following the program phase, and a second verify operation (e.g., a fine verify operation) is performed in a second verify phase (e.g., a fine verify phase) following the first verify phase. The result of the comparison during the first loop may include comparing the threshold voltage Vt of the memory cell with the high verify level VH and/or the low verify level VL. This will be discussed in detail later in FIG. 8A. In some implementations, the low verify level VL may be a coarse verify voltage (e.g., a first verify voltage applied during the first verify operation in the first verify phase), while the high verify level VH may be a fine verify voltage (e.g., a second verify voltage applied during the second verify operation in the second verify phase). As such, the coarse verify operation is performed before the fine verify operation. And both of the coarse verify operation and the fine verify operation are performed after the program operation, as shown in FIG. 6F.

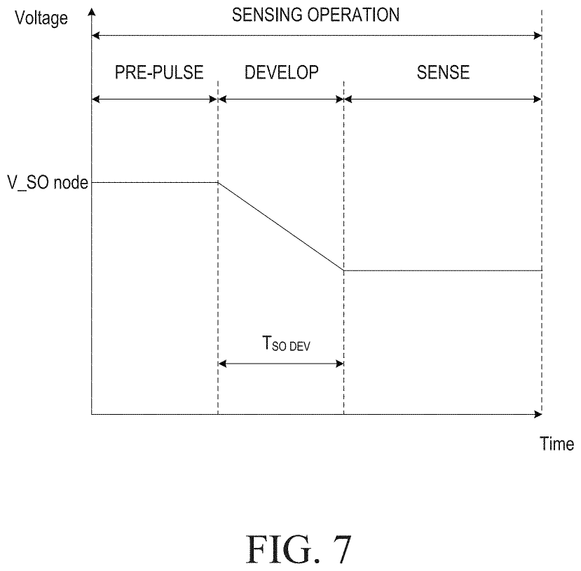

FIG. 7 is a voltage-time (V-t) chart illustrating a variation in a sense-out (SO) node voltage according to a program verify operation, according to some implementations of the present disclosure. Referring to FIG. 7, the horizontal axis represents time, and the vertical axis represents a voltage V_SO node of the sense-out node SO. In some implementations, the program verify operation may include at least one sensing operation. In the sensing operation, at least a pre-verify operation may be performed by applying a pre-pulse voltage to the sense-out node SO during the pre-pulse phase. After that, the voltage level of the sense-out node SO decreases by discharging the SO node capacitor corresponding to the selected bit line to a specific voltage during a develop phase. After that, an operation of sensing the voltage of the SO node is performed during a sensing phase. In some implementations, during the development phase, the voltage level of the sense-out node SO changes according to the voltage level of a bit line. In this case, the length of the develop phase may correspond to a SO development time T_{SO DEV}.

FIG. 8A is a flowchart of a programming method 800 for programming in memory devices (e.g., may correspond to memory device 100 or other memory device in the present disclosure). The method applies incremental-step-pulse programming (ISPP) with multiple bit line bias voltages (e.g., 3 bit line (3BL), 4 bit line (4BL), or more bit line bias voltages) to a memory cell of the memory device with predetermined parameters including a high verify level VH, a low verify level VL, a system voltage Vdd, and an intermediate voltage Vb. The method may be applied to a plurality of the memory cells. In some implementations, it can be 4BL program scheme. For example, a high verify level VH, a middle verify level VM, a low verify level VL, a system voltage Vdd, a first intermediate voltage Vb1, and a second intermediate voltage Vb2 may be used. In some implementations, more intermediate voltages may be used to divide threshold voltages of the memory cells into different voltage verify levels and thus apply the different memory cells with different bias voltages in the next loop of the program verify operation. The method may include the following steps: Step 802: Apply at least one programming pulse to a word line corresponding to a memory cell of the memory device in a first loop of the program verify operation; apply the low voltage such as 0 V on the bit line associated with the memory cell of the memory device; Step 804: Compare the threshold voltage Vt of the memory cell with the high verify level VH and/or the low verify level VL; if the threshold voltage Vt of the memory cell is higher than the high verify level VH, proceed to Step 806; if the threshold voltage Vt of the memory cell is higher than the low verify level VL but lower than the high verify level VH, proceed to Step 808; if the threshold voltage Vt of the memory cell is lower than the low verify level VL, proceed to Step 810: Step 806: Apply the system voltage Vdd on the bit line associated with the memory cell in a next loop (e.g., a second loop of the program verify operation); Step 808: Apply the first intermediate voltage Vb on the bit line associated with the memory cell in the next loop (e.g., the second loop of the program verify operation): Step 810: Apply the low voltage on the bit line associated with the memory cell in the next loop (e.g., the second loop of the program verify operation).

After the above steps, end the first loop of the program verify operation and start the next loop of the program verify operation (e.g., the second loop of the program verify operation). In some implementations, the loops of the program verify operation may be performed until parts or all the memory cells are programmed to the target program state.

FIGS. 8B and 8C are block diagrams of word line subsets according to an implementation of the present disclosure. When the word lines are grouped into word line subsets by SO node development time (as mentioned above) or by other methods, it can be used to implement the programming method 800 for programming in memory devices.

For example, as shown in FIG. 8B, word lines WL0˜WL63 are grouped in three word line subsets Group 1˜Group 3, wherein each word line subset is defined by sense-out (SO) node development time—a period of time determined by discharging SO node capacitor corresponding to the selected bit line to a specific voltage. Specifically, a first word line subsets Group 1 having word lines WL0˜WL20 are defined by a first range of SO node development time, a second word line subsets Group 2 having word lines WL21˜WL40 are defined by a second range of SO node development time, and a third word line subsets Group 3 having word lines WL41˜WL63 are defined by a third range of SO node development time. In some implementations, first word line subsets Group 1, second word line subsets Group 2, and third word line subsets Group 3 are programmed sequentially, and a first range of SO node development time, a second range of SO node development time, and a third range of SO node development time increase sequentially. In another example, as shown in FIG. 8C, word lines WL0˜WL127 are grouped in six word line subsets Group 1 Group 6, wherein each word line subset is defined by the SO node development time. Specifically, a first word line subsets Group 1 having word lines WL0˜WL20 are defined by a first range of SO node development time, a second word line subsets Group 2 having word lines WL21˜WL40 are defined by a second range of SO node development time, a third word line subsets Group 3 having word lines WL41˜WL63 are defined by a third range of SO node development time, a fourth word line subsets Group 4 having word lines WL64˜WL84 are defined by a fourth range of SO node development time, a fifth word line subsets Group 5 having word lines WL85˜WL105 are defined by a fifth range of SO node development time, and a sixth word line subsets Group 6 having word lines WL106˜WL127 are defined by a sixth range of SO node development time. In some implementations, first word line subsets Group 1, second word line subsets Group 2, third word line subsets Group 3, fourth word line subsets Group 4, fifth word line subsets Group 5, sixth word line subsets Group 6 are programmed sequentially, and a first range of SO node development time, a second range of SO node development time, a third range of SO node development time, a fourth range of SO node development time, a fifth range of SO node development time, a sixth range of SO node development time increase sequentially. That is, the earlier programmed word line subsets are defined by smaller SO node development time, while the later programmed word line subsets are defined by larger SO node development time. In some implementations, each word line subset defined by SO node development time can be further defined by the formula: I_coarse_sense=C_so*ΔV_so/t_sodev_coarse, where I_coarse_sense is the coarse verify current. C_so is the capacitor connected to the SO node (e.g., an SO node capacitor), ΔV_so is a voltage difference between fine verify operation and coarse verify operation in the SO node, and t_sodev_coarse is the SO node development time during the coarse verify operation. Since smaller SO node development time t_sodev_coarse means larger coarse verify current I_coarse_sense according to the above formula, the earlier programmed word line subsets are verified by larger coarse verify current, while the later programmed word line subsets are verified by smaller coarse verify current. By using the above-mentioned grouping method to program verify the memory device, the ΔV_so of fine verify operation and coarse verify operation can be retained constant.

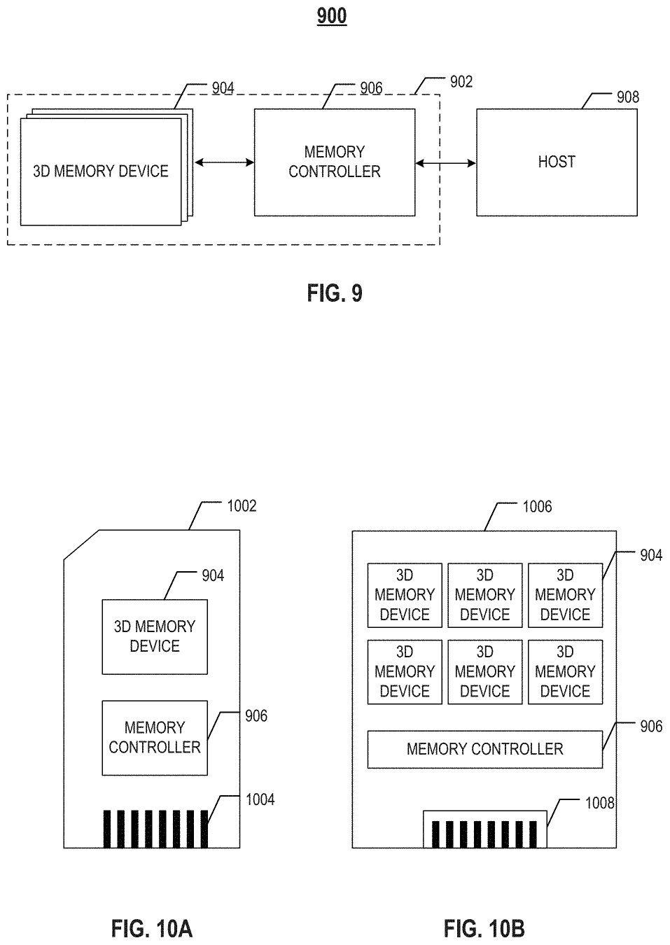

FIG. 9 illustrates a block diagram of a system 900 having a memory device, according to some aspects of the present disclosure. System 900 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 9, system 900 can include a host 908 (e.g., may correspond to, for example, host 311 in FIG. 4C) and a memory system 902 (e.g., may correspond to, for example, memory system 320 in FIG. 4C) having one or more memory devices 904 (e.g., may correspond to, for example, memory device 100 in FIG. 3B. 4A, 4B, or 4C) and a memory controller 906 (e.g., may correspond to, for example, memory controller 300 in FIG. 4C). Host 908 can be a processor of an electronic device, such as a central processing unit (CPU), or a system-on-chip (SoC), such as an application processor (AP). Host 908 can be configured to send or receive the data to or from memory devices 904.

Memory devices 904 can be any memory devices disclosed herein, such as memory devices 100. In some implementations, each memory device 904 includes a memory device, as described above in detail.

Memory controller 906 is coupled to memory device 904 and host 908 and is configured to control memory device 904, according to some implementations. Memory controller 906 can manage the data stored in memory device 904 and communicate with host 908. In some implementations, memory controller 906 is designed for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 906 is designed for operating in a high duty-cycle environment SSDs or embedded multi-media-cards (eMMCs) used as data storage for mobile devices, such as smartphones, tablets, laptop computers, etc., and enterprise storage arrays. Memory controller 906 can be configured to control operations of memory device 904, such as read, erase, and program operations. Memory controller 906 can also be configured to manage various functions with respect to the data stored or to be stored in memory device 904 including, but not limited to bad-block management, garbage collection, logical-to-physical address conversion, wear leveling, etc. In some implementations, memory controller 906 is further configured to process error correction codes (ECCs) with respect to the data read from or written to memory device 904. Any other suitable functions may be performed by memory controller 906 as well, for example, formatting memory device 904. Memory controller 906 can communicate with an external device (e.g., host 908) according to a particular communication protocol. For example, memory controller 906 may communicate with the external device through at least one of various interface protocols, such as a USB protocol, an MMC protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

Memory controller 906 and one or more memory devices 904 can be integrated into various types of storage devices, for example, be included in the same package, such as a universal Flash storage (UFS) package or an eMMC package. That is, memory system 902 can be implemented and packaged into different types of end electronic products. In one example as shown in FIG. 10A, memory controller 906 and a single memory device 904 may be integrated into a memory card 1002. Memory card 1002 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc. Memory card 1002 can further include a memory card connector 1004 coupling memory card 1002 with a host (e.g., host 908 in FIG. 9). In another example as shown in FIG. 10B, memory controller 906 and multiple memory devices 904 may be integrated into an SSD 1006. SSD 1006 can further include an SSD connector 1008 coupling SSD 1006 with a host (e.g., host 908 in FIG. 9). In some implementations, the storage capacity and/or the operation speed of SSD 1006 is greater than those of memory card 1002.

Those skilled in the art will readily observe that numerous modifications and alterations of the device and method may be made while retaining the teachings of the disclosure. Accordingly, the above disclosure should be construed as limited only by the metes and bounds of the appended claims.

What is claimed is:

1. A memory device, comprising:
a memory array including memory cells;
bit lines coupled to the memory cells;
word lines coupled to the memory cells;
a column decoder coupled to the bit lines;
a sensing circuit coupled to the column decoder; and
a controller coupled the memory array and configured to:
perform a first verify operation on a first memory cell of the memory cells according to a first develop time; and
perform a second verify operation on a second memory cell of the memory cells according to a second develop time, wherein the first develop time is different from the second develop time.

2. The memory device of claim 1, wherein the first verify operation comprises a first coarse verify operation, and the second verify operation comprises a second coarse verify operation.

3. The memory device of claim 1, wherein the memory array further comprises a memory string, the memory string comprises the first memory cell corresponding to a first word line and the second memory cell corresponding to a second word line.

4. The memory device of claim 3, wherein the controller is further configured to:
perform the first verify operation on the first memory cell of the memory cells according to the first develop time by applying a first verify voltage to the first word line coupled to the first memory cell; and
perform the second verify operation on the second memory cell of the memory cells according to the second develop time by applying a second verify voltage to the second word line coupled to the second memory cell.

5. The memory device of claim 1, wherein performing the first verify operation on the first memory cell of the memory cells according to the first develop time is under a first temperature, and performing the second verify operation on the second memory cell of the memory cells according to the second develop time is under a second temperature, wherein the first temperature is different from the second temperature.

6. The memory device of claim 5, wherein the first develop time is longer than the second develop time, and the first temperature is lower than the second temperature.

7. The memory device of claim 5, wherein the first memory cell is the second memory cell.

8. The memory device of claim 1, wherein the first verify operation comprises a 3 bit line (3BL) coarse verify operation, and the second verify operation comprises a 3BL fine verify operation.

9. A memory device, comprising:
a memory array including memory cells;
bit lines coupled to the memory cells;
word lines coupled to the memory cells; and
a control logic coupled the memory array and configured to:
perform a program operation on a first memory cell of the memory cells;
perform a first verify operation on the first memory cell of the memory cells according to a first develop time; and
perform a second verify operation on the first memory cell of the memory cells according to a second develop time, wherein the first develop time is different from the second develop time.

10. The memory device of claim 9, wherein the first verify operation comprises a coarse verify operation, and the second verify operation comprises a fine verify operation.

11. The memory device of claim 10, wherein a first verify voltage of the first verify operation is lower than a second verify voltage of the second verify operation.

12. The memory device of claim 9, wherein the memory array further comprises a memory string, the memory string comprises the first memory cell corresponding to a first word line and the second memory cell corresponding to a second word line.

13. The memory device of claim 12, wherein performing the first verify operation on the first memory cell of the memory cells according to the first develop time is under a first temperature, and performing the second verify operation on the second memory cell of the memory cells according to the second develop time is under a second temperature, wherein the first temperature is different from the second temperature.

14. The memory device of claim 13, wherein the first develop time is longer than the second develop time, and the first temperature is lower than the second temperature.

15. The memory device of claim 13, wherein the first memory cell is the second memory cell.

16. The memory device of claim 9, wherein the first verify operation comprises a 3 bit line (3BL) coarse verify operation, and the second verify operation comprises a 3BL fine verify operation.

17. A method for operating a memory device, comprising:
performing a first verify operation on a first memory cell of memory cells of a memory array according to a first develop time; and
performing a second verify operation on a second memory cell of the memory cells according to a second develop time, wherein the first develop time is different from the second develop time.

18. The method of claim 17, wherein the memory array further comprises a memory string, the memory string comprises the first memory cell corresponding to a first word line, and the second memory cell corresponding to a second word line, wherein the method further comprises:
performing the first verify operation on the first memory cell of the memory cells according to the first develop time by applying a first verify voltage to the first word line coupled to the first memory cell; and
performing the second verify operation on the second memory cell of the memory cells according to the second develop time by applying a second verify voltage to the second word line coupled to the second memory cell.

19. The memory device of claim 17, wherein performing the first verify operation on the first memory cell of the memory cells according to the first develop time is under a first temperature, and performing the second verify operation on the second memory cell of the memory cells according to the second develop time is under a second temperature, wherein the first develop time is longer than the second develop time, and the first temperature is lower than the second temperature.

20. A system comprising:
a memory device comprising:
a memory array including memory cells;
bit lines coupled to the memory cells;
word lines coupled to the memory cells; and
a control logic coupled the memory array and configured to:
perform a program operation on a first memory cell of the memory cells;
perform a first verify operation on the first memory cell of the memory cells according to a first develop time; and
perform a second verify operation on the first memory cell of the memory cells according to a second develop time, wherein the first develop time is different from the second develop time; and
a memory controller coupled to the memory device and configured to operate the memory device.
